(19) United States
(12) Patent Application Publication
(10) Pub. No.: US 2025/0271513 A1
(43) Pub. Date: Aug. 28, 2025

(54) RESONANT MAGNETIC SENSOR

(71) Applicant: Murata Manufacturing Co., Ltd., Nagaokakyo-shi (JP)

(72) Inventor: Yuuki OOI, Nagaokakyo-shi (JP)

(21) Appl. No.: 19/206,224

(22) Filed: May 13, 2025

Related U.S. Application Data
(63) Continuation of application No. PCT/JP2023/027003, filed on Jul. 24, 2023.

(30) Foreign Application Priority Data
Dec. 9, 2022 (JP) 2022-197333

(51) Int. Cl. G01R 33/00; G01R 33/09; H03H 9/15; H03H 9/19

(52) U.S. Cl. CPC G01R 33/0047; G01R 33/0017; G01R 33/09; H03H 9/19; H03H 2009/155

(57) ABSTRACT

A resonant magnetic sensor that detects a magnetic field includes: a vibrating element that includes a vibrating portion having a first main surface and a second main surface that faces away from the first main surface, a first electrode on the first main surface of the vibrating portion, and a second electrode on the second main surface of the vibrating portion; a first lid on a side of the vibrating element closer to the first electrode; a second lid on a side of the vibrating element closer to the second electrode; a magnetic film on the vibrating portion of the vibrating element; and a film magnet spaced away from the vibrating portion in an interior space enclosed by the first lid and the second lid such that a magnetic field is applied to the magnetic film.

### CROSS REFERENCE TO RELATED APPLICATIONS

The present application is a continuation of International application No. PCT/JP2023/027003, filed Jul. 24, 2023, which claims priority to Japanese Patent Application No. 2022-197333, filed Dec. 9, 2022, the entire contents of each of which are incorporated herein by reference.

### TECHNICAL FIELD

The present disclosure relates to a resonant magnetic sensor.

### BACKGROUND ART

Generally, a magnetic sensor that detects changes in an external magnetic field by using magnetostriction effects is known. For example, Patent Document 1 discloses a magnetic sensor that vibrates a magnetic thin film (magnetic sensor element) formed on a vibrating body and detects changes in the external magnetic field by obtaining, as changes in the resonant frequency, changes in the Young's modulus of the thin film due to changes in the external magnetic field. In addition, Patent Document 2 discloses a magnetic sensor that applies a bias magnetic field by laminating a thin-film magnet on a magnetic sensor element.
Patent Document 1: Japanese Unexamined Patent Application Publication No. 2005-90971
Patent Document 2: International Publication No. 2021/245785

### SUMMARY OF THE DISCLOSURE

However, the structure in Patent Document 1 has low sensor sensitivity in the vicinity of zero magnetic field and is not suitable for sensing of minute magnetic fields. In addition, when the structure in Patent Document 2 is applied to a resonant magnetic sensor with a vibrating portion, a thin-film magnet is provided in the vibrating portion. As a result, it is conceivable that the vibration of the vibrating portion is hindered and characteristics thereof degrade.

The present disclosure addresses such circumstances with an object of providing a high-sensitive resonant magnetic sensor.

According to an aspect of the present disclosure, there is provided a resonant magnetic sensor that detects a magnetic field, the resonant magnetic sensor including: a vibrating element that includes a vibrating portion having a first main surface and a second main surface that faces away from the first main surface, a first electrode on the first main surface of the vibrating portion, and a second electrode on the second main surface of the vibrating portion; a first lid on a side of the vibrating element closer to the first electrode; a second lid on a side of the vibrating element closer to the second electrode; a magnetic film on the vibrating portion of the vibrating element; and a film magnet spaced away from the vibrating portion in an interior space enclosed by the first lid and the second lid such a magnetic field is applied to the magnetic thin film.

According to the present disclosure, the high-sensitive resonant magnetic sensor can be provided.

### BRIEF DESCRIPTION OF THE DRAWINGS

FIG. 1 is a perspective view schematically illustrating a resonant magnetic sensor according to a first embodiment.

FIG. 2 is a plan view schematically illustrating the structure of a quartz crystal vibrating element of the resonant magnetic sensor according to the first embodiment.

FIG. 3 is a cross-sectional view schematically illustrating the resonant magnetic sensor according to the first embodiment.

FIG. 4 is a diagram illustrating sensor sensitivity and sensor output with respect to a magnetic field applied to the magnetic sensor when no bias magnetic field is applied.

FIG. 5 is a diagram illustrating sensor sensitivity and sensor output with respect to a magnetic field applied to the magnetic sensor when a bias magnetic field is applied.

FIG. 6 is a cross-sectional view schematically illustrating a resonant magnetic sensor according to a second embodiment.

FIG. 7 is a cross-sectional view schematically illustrating a resonant magnetic sensor according to a third embodiment.

FIG. 8 is a cross-sectional view schematically illustrating a resonant magnetic sensor according to a fourth embodiment.

### DESCRIPTION OF THE PREFERRED EMBODIMENTS

Embodiments of the present disclosure will be described with reference to the drawings. The drawings of the present embodiments are illustrative and the dimensions and shapes of individual portions are schematic, and accordingly, the technical scope of the present disclosure should not be understood as limited to the embodiments.

In the drawings, an orthogonal coordinate system having an X axis, a Y′ axis, and a Z′ axis may be illustrated to clarify the mutual relationship between the drawings and to assist understanding of the positional relationship of individual members. The X axes, the Y′ axes, and the Z′ axes in the diagrams correspond to each other. The X axis, Y′ axis, and Z′ axis correspond to the crystallographic axes of the quartz crystal blank described later. The X axis corresponds to the electric axis (polar axis), the Y axis corresponds to the mechanical axis, and the Z axis corresponds to the optical axis of the quartz crystal. The Y′ axis and the Z′ axis are obtained by rotating the Y axis and the Z axis about the X axis by 35 degrees 15 minutes±1 minute 30 seconds in the direction from the Y axis to the Z axis.

In the following description, the direction parallel to the X axis is referred to as an X-axis direction, the direction parallel to the Y′ axis is referred to as a Y′-axis direction, and the direction parallel to the Z′ axis is referred to as a Z′-axis direction. In addition, the direction of the arrowhead of each of the X axis, the Y′ axis, and the Z′ axis is referred to as positive or + (plus), and the direction opposite to the arrowhead is referred to as negative or − (minus). It should be noted that, for convenience, the +Y′-axis direction is referred to as an upward direction and the −Y′-axis direction referred to as a downward direction, but the upward and downward orientations of the quartz crystal vibrating element 10 are not limited. In addition, the plane defined by the X axis and the Z′ axis is referred to as a Z′X plane, and the same applies to the planes defined by the other axes.

### First Embodiment

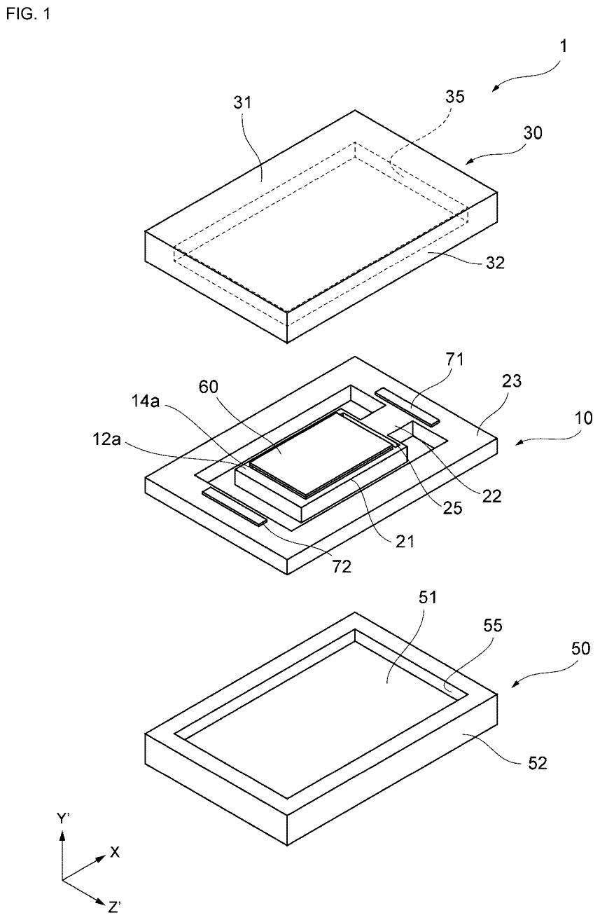

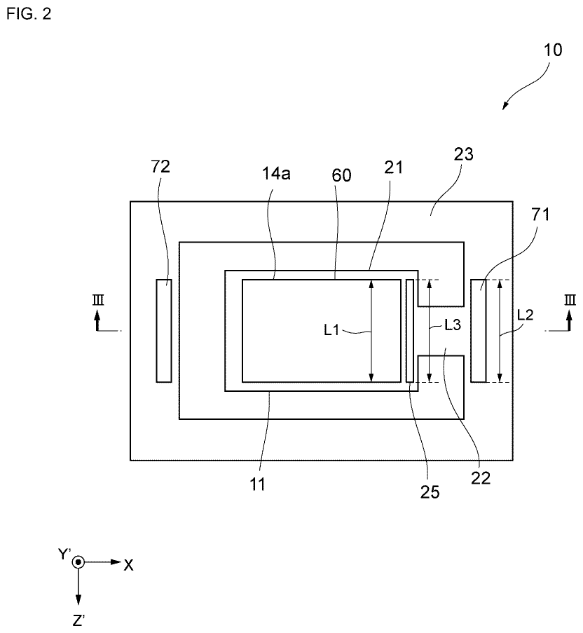

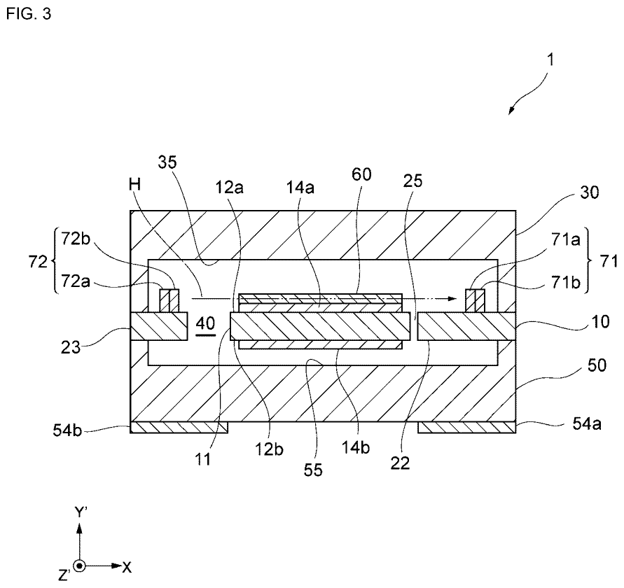

The structure of a resonant magnetic sensor 1 according to a first embodiment of the present disclosure will be described with reference to FIGS. 1, 2, and 3. FIG. 1 is an exploded perspective view schematically illustrating the resonant magnetic sensor 1 according to the present embodiment. FIG. 2 is a plan view schematically illustrating the structure of a quartz crystal vibrating element of the resonant magnetic sensor 1 according to the first embodiment. FIG. 3 is a cross-sectional view schematically illustrating the structure of the resonant magnetic sensor 1 according to the first embodiment.

The resonant magnetic sensor 1 according to the present embodiment includes a quartz crystal vibrating element 10, an upper (first) lid 30, a lower (second) lid 50, a magnetic thin film 60, and thin-film magnets 71 and 72. In the following description, a resonant magnetic sensor including a piezoelectric vibrating element that outputs a resonant frequency for detecting magnetic fields is used as an example of the resonant magnetic sensor 1. In addition, in the following description, the quartz crystal vibrating element 10 including a quartz crystal blank is used as an example of the piezoelectric vibrating element. The quartz crystal blank 11 is a type of a piezoelectric substance (piezoelectric element) that vibrates in accordance with an applied voltage. It should be noted that the piezoelectric vibrating element is not limited to the quartz crystal vibrating element 10 and may also include other piezoelectric substances, such as ceramic. In addition, the piezoelectric vibrating element may also be a MEMS vibrating element manufactured by MEMS technology. In addition, the resonant magnetic sensor according to the present embodiment detects an external magnetic field in accordance with changes in the resonant frequency of the piezoelectric vibrating element caused by the external magnetic field. It should be noted that the aspect of vibration of the resonant magnetic sensor according to the present embodiment is not limited to the piezoelectric type described above and may also be, for example, an electrostatic type driven by electrostatic force.

The quartz crystal vibrating element 10 (corresponding to an example of the vibrating element) vibrates a quartz crystal by using piezoelectric effects and performs conversion between mechanical energy and electrical energy. The quartz crystal vibrating element 10 includes an AT-cut quartz crystal blank 11. The AT-cut quartz crystal blank 11 is cut to have, as a main surface, the XZ′ plane specified by the X axis and the Z′ axis when the Y axis and Z axis are rotated about the X axis by 35 degrees 15 minutes±1 minute 30 seconds in the direction from the Y axis to the Z axis among the X axis, the Y axis, and the Z axis that are the crystallographic axes of a synthetic quartz crystal.

It should be noted that the rotation angles of the Y′ axis and Z′ axis of the AT-cut quartz crystal blank 11 may be inclined within the range of −5 degrees or more and 15 degrees or less from 35 degrees 15 minutes. In addition, different cut other than AT cut, such as BT cut, GT cut, SC cut, or the like may be applied as the cut angle of the quartz crystal blank 11.

The quartz crystal vibrating element including the AT-cut quartz crystal blank has high frequency stability over a wide temperature range. In addition, the AT-cut quartz crystal vibrating element exhibits excellent aging characteristics and can be manufactured at a low cost. Furthermore, the AT-cut quartz crystal vibrating element uses a thickness shear vibration mode as main vibration.

The quartz crystal vibrating element 10 includes a pair of excitation electrodes. An alternating electric field is applied across this pair of excitation electrodes. As a result, the vibrating portion of the quartz crystal blank 11 vibrates at a predetermined oscillation frequency in the thickness shear vibration mode, and resonance characteristics corresponding to this vibration are obtained.

As described above, since the main vibration of the quartz crystal vibrating element 10 is in the thickness shear vibration mode, it is possible to easily achieve a quartz crystal vibrating element that performs thickness shear vibration at MHz frequencies by using, for example, the AT-cut quartz crystal blank 11.

The quartz crystal blank 11 has a first main surface 12a and a second main surface 12b that are XZ′ planes and face away from each other. The quartz crystal blank 11 has a flat plate shape. Accordingly, the first main surface 12a and the second main surface 12b of the quartz crystal blank 11 are flat surfaces. It should be noted that the quartz crystal blank 11 is not limited to a flat plate, and the central portion thereof may be raised or recessed.

In the AT-cut quartz crystal blank 11, there are a long-side direction in which the long side parallel to the X-axis direction extends, a short-side direction in which the short side parallel to the Z′-axis direction extends, and a thickness direction in which the thickness parallel to the Y′-axis direction extends. The quartz crystal blank 11 is rectangular in plan view of the first main surface 12a of the quartz crystal blank 11 (simply referred to below as in plan view). The quartz crystal blank 11 may be polished to a predetermined thickness after the quartz crystal blank 11 with a greater thickness is joined to the lower lid 50.

It should be noted that the planar shape of the quartz crystal blank 11 is not limited to a rectangular shape. The planar shape of the quartz crystal blank 11 may be a polygonal shape, a circular shape, an elliptical shape, or a combination thereof.

The quartz crystal vibrating element 10 includes a vibrating portion 21, a holding arm 22, and a holding portion 23. The vibrating portion 21 includes a quartz crystal blank 11 and a pair of excitation electrodes. The pair of excitation electrodes includes a first excitation electrode 14a (corresponding to an example of the upper electrode) and a second excitation electrode 14b (corresponding to an example of the lower electrode). The first excitation electrode 14a is provided on the first main surface 12a of the vibrating portion 21, and the second excitation electrode 14b is provided on the second main surface 12b of the vibrating portion 21. The first excitation electrode 14a and the second excitation electrode 14b are provided to face each other with the quartz crystal blank 11 therebetween. The first excitation electrode 14a and the second excitation electrode 14b are rectangular in plan view of the first main surface 12a and these excitation electrodes substantially overlap each other on the XZ′ plane.

It should be noted that the shapes of the first excitation electrode 14a and the second excitation electrode 14b are not limited to a rectangular shape and may also be a polygonal shape, a circular shape, an elliptical shape, or a combination thereof.

The quartz crystal vibrating element 10 includes extended electrodes and connection electrodes (not illustrated) through which the first excitation electrode 14a is electrically connected to an outer electrode 54a, and the second excitation electrode 14b is electrically connected to an outer electrode 54b. An alternating electric field is applied to the first excitation electrode 14a and the second excitation electrode 14b via these outer electrodes 54a and 54b, and accordingly, the vibrating portion 21 (specifically, the portion of the quartz crystal blank 11 in which the first excitation electrode 14a and the second excitation electrode 14b are provided) vibrates in a predetermined vibration mode.

The materials of the first excitation electrode 14a, the second excitation electrode 14b, the extended electrode, and the connection electrode are, for example, aluminum (Al), molybdenum (Mo), or gold (Au). In addition, each of the electrodes described above may be a multilayer body including a titanium (Ti) layer provided closer to the quartz crystal blank 11 and a gold (Au) layer provided closer to the surface.

The quartz crystal vibrating element 10 is housed in an interior space 40 formed between the upper lid 30 and the lower lid 50. For example, the interior space 40 formed by the upper lid 30 and the lower lid 50 is hermetically sealed. It should be noted that this interior space 40 may be hermetically sealed in a vacuum state or may be hermetically sealed with the interior space 40 filled with a gas, such as an inert gas.

The vibrating portion 21 is a portion of the quartz crystal vibrating element 10 and is located at the center of the interior space 40. In addition, as illustrated in FIG. 3, the vibrating portion 21 has the first main surface 12a and the second main surface 12b that faces away from the first main surface 12a. The vibrating portion 21 includes the first excitation electrode 14a provided on the first main surface 12a and the second excitation electrode 14b provided on the second main surface 12b. The first excitation electrode 14a is provided on a surface of the quartz crystal blank 11 that faces the upper lid 30, and the second excitation electrode 14b is provided on a surface of the quartz crystal blank 11 that faces the lower lid 50. In addition, the magnetic thin film 60 is provided on a surface of the first excitation electrode 14a that faces the upper lid 30.

The holding arm 22 is located in the interior space 40 like the vibrating portion 21 and connects the vibrating portion 21 and the holding portion 23 to each other. An extended electrode, which is not illustrated, can be formed in the holding arm 22 to route the first excitation electrode 14a and the second excitation electrode 14b to a connection electrode provided in the holding portion 23.

The holding portion 23 is formed in, for example, a frame shape that surrounds the vibrating portion 21 in plan view. In addition, the holding portion 23 is not limited to a frame shape that fully surrounds the periphery of the vibrating portion 21 and may be around at least a portion of the periphery of the vibrating portion. The holding portion 23 is joined to the upper lid 30 and the lower lid 50 in the vertical direction. The holding portion 23 is connected to the holding arm 22. In addition, the thin-film magnets 71 and 72 are provided on the holding portion 23 and apply a magnetic field H to the magnetic thin film 60 on the vibrating portion 21. In a modification, the thin-film magnet 71 may be provided on a surface of the holding arm 22 that faces the upper lid 30 instead of in a region of the holding portion 23.

A through-hole 25 is provided in the vibrating portion 21. Specifically, the through-hole 25 is provided in a region between the holding arm 22 and the magnetic thin film 60. The through-hole 25 passes through the vibrating portion 21 in the thickness direction of the vibrating portion 21 (the Y′-axis direction in the example illustrated in FIG. 3). Alternatively, the through-hole 25 is formed in, for example, a slit shape. In this case, the slit-shaped through-hole 25 extends in a direction that intersects the direction in which the magnetic thin film 60 and the holding arm 22 are arranged in plan view of the quartz crystal vibrating element 10. A length L1 of the magnetic thin film 60 in the Z′-axis direction, a length L2 of the thin-film magnet 71 in the Z′-axis direction, and a length L3 of the through-hole in the Z′-axis direction are all approximately the same in the present embodiment as illustrated in FIG. 2, but the lengths are not limited to this example. For example, when L3 is greater than L1 or L2, the confinement capability of vibration generated by the vibrating portion 21 can be improved. An example in which a through-hole 25 is provided in the vibrating portion 21 has been described in the present embodiment, but the through-hole 25 does not necessarily need to be formed. In addition, a recessed portion recessed in the Y′-axis direction may be provided instead of the through-hole 25.

The upper lid 30 has an upper surface portion 31 that faces away from the quartz crystal vibrating element 10 and side surface portions 32 that extend in the negative Y′ direction from the outer periphery of the upper surface portion 31, and the upper surface portion 31 and the side surface portions 32 form a recessed portion 35. The upper lid 30 is joined to an upper surface side of the holding portion 23. The dimensions of the upper lid 30 in plan view are the same or substantially the same as the dimensions of the quartz crystal vibrating element 10.

The interior space 40 is a space formed internally by the upper lid 30 and the lower lid 50 and includes the recessed portion 35 of the upper lid 30 and a recessed portion 55 of the lower lid 50. The vibrating portion 21 and the holding arm 22 are provided in the interior space 40, which forms a vibration space of the quartz crystal vibrating element 10.

The lower lid 50 has a lower surface portion 51 that faces away from the quartz crystal vibrating element 10 and side surface portions 52 that extend in the positive Y′ direction from the outer periphery of the lower surface portion 51, and the lower surface portion 51 and the side surface portions 52 form the recessed portion 55. The lower lid 50 is joined to a lower surface side of the holding portion 23. In addition, the outer electrodes 54a and 54b are provided on the side opposite to a surface of the lower lid 50 that faces the vibrating portion 21. The outer electrodes 54a and 54b are electrically connected to the first connection electrode and the second connection electrode.

The magnetic thin film 60 is provided on the first excitation electrode 14a of the vibrating portion 21. For example, the magnetic thin film 60 is formed to have the same dimensions in plan view as the first excitation electrode 14a. The Young's modulus of the magnetic thin film 60 changes when an external magnetic field is applied to the magnetic thin film 60. When the magnetic thin film 60 is provided on the vibrating portion 21, changes in Young's modulus can be detected as changes in the resonant frequency. The magnetic thin film 60 provided separately from the quartz crystal blank 11 functions as a magnetic material in the first embodiment, but the present disclosure is not limited to this example. For example, a multiferroic that has functions as a magnetic material and a piezoelectric substance may be used.

As illustrated in FIG. 2, the thin-film magnets 71 and 72 are provided away from the vibrating portion 21 in an interior space 40 enclosed by the upper lid 30 and lower lid 50 so as to apply a magnetic field H to the magnetic thin film 60. The thin-film magnet 71 is provided in a region (corresponding to an example of the first region) in the holding portion 23 that is connected to the holding arm 22, and the thin-film magnet 72 is provided in a region (corresponding to an example of the second region) in the holding portion 23 that is opposite to the region described above. These thin-film magnets 71 and 72 are provided on both sides of the magnetic thin film 60 with the magnetic thin film 60 therebetween. In addition, as illustrated in FIG. 3, at least portions of the thin-film magnets 71 and 72 are located on the same plane as at least a portion of the magnetic thin film 60. The thin-film magnet 71 has a south pole 71a and a north pole 71b. The south pole 71a is disposed to face the inside of the resonant magnetic sensor 1. The north pole 71b is disposed to face the outside of the resonant magnetic sensor 1. Similarly, the thin-film magnet 72 has a south pole 72a and a north pole 72b. Unlike the thin-film magnet 71, the south pole 72a is disposed to face the outside of the resonant magnetic sensor 1, and the north pole 72b is disposed to face the inside of the resonant magnetic sensor 1. Since the south pole 71a of the thin-film magnet 71 and the north pole 72b of the thin-film magnet 72 are disposed to face each other with the magnetic thin film 60 therebetween as described above, the magnetic field H from the north pole 72b to the south pole 71a is generated, and the magnetic field H is applied to the magnetic thin film 60. It should be noted that the positions of the south pole and north pole of each of the thin-film magnets may be interchanged with each other. It should be noted that the thin-film magnet 71 is provided on the holding portion 23 in the illustrated example, but the present disclosure is not limited to this example and the thin-film magnet 71 may also be provided, for example, on the holding arm 22.

The length L1 of the magnetic thin film 60 in the Z′-axis direction and the length L2 of the thin-film magnet 71 in the Z′-axis direction are approximately the same in plan view in FIG. 2, but the present disclosure is not limited to this example. When, for example, the length L2 of the thin-film magnet 71 in the Z′-axis direction is greater than the length L1 of the magnetic thin film 60 in the Z′-axis direction, a uniform magnetic field can be applied to the entire magnetic thin film 60. It should be noted that the sizes of the thin-film magnets 71 and 72 may be the same as each other.

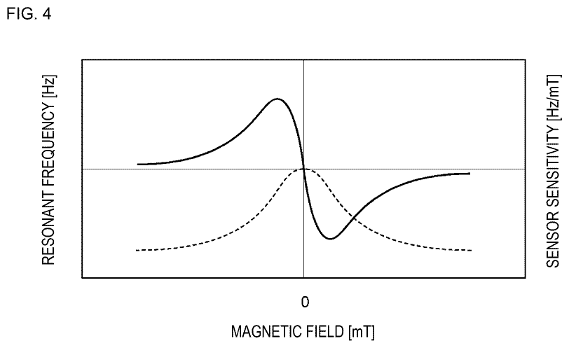

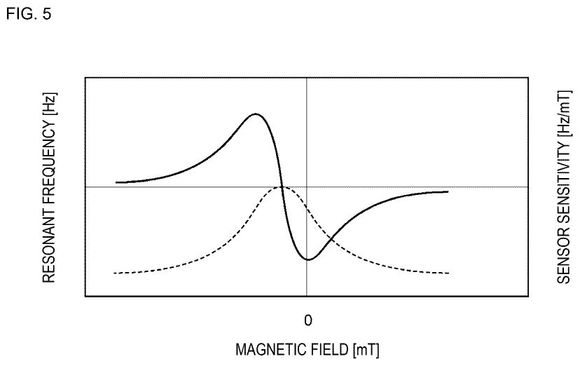

Next, the effects of a bias magnetic field will be described with reference to FIGS. 4 and 5. FIG. 4 is a diagram illustrating sensor sensitivity and sensor output with respect to a magnetic field applied to the magnetic sensor when a bias magnetic field is not applied, and FIG. 5 is a diagram illustrating sensor sensitivity and sensor output with respect to a magnetic field applied to the magnetic sensor when a bias magnetic field is applied. In FIGS. 4 and 5, the horizontal axis represents the magnetic field [mT] applied to a magnetic sensor, and the vertical axis represents the resonant frequency [Hz] of a quartz crystal vibrating element and the sensitivity [Hz/mT] of the sensor. In FIG. 4, the resonant frequency reaches the maximum and the sensor sensitivity is substantially zero in the vicinity of zero magnetic field. In this case, detection a minute magnetic field is difficult. In contrast, in FIG. 5, application of a bias magnetic field can increase the sensor sensitivity in the vicinity of zero magnetic field. In addition, detection within a numerical range that has good linearity between the magnetic field and the resonant frequency enables detection of minute fluctuations in the magnetic field. As illustrated in FIGS. 4 and 5, application of a bias magnetic field enables measurement of the magnetic field in a numerical range in which accurate measurement is difficult because sensitivity is originally low.

As described above, the resonant magnetic sensor 1 according to the present embodiment can achieve a magnetic sensor that can detect the measurement of a magnetic field with high sensitivity in the vicinity of zero magnetic field in which sensitivity is originally low, by applying a bias magnetic field to the magnetic thin film 60. In addition, by the thin-film magnets 71 and 72 being provided away from the vibrating portion 21, the magnetic field H can be applied to the magnetic thin film 60 without the vibration characteristics of the quartz crystal vibrating element 10 being hindered.

In addition, since the thin-film magnets 71 and 72 are provided with the vibrating portion 21 therebetween and the south pole 71a and the north pole 72b thereof face each other, a magnetic field H can be applied in parallel to the thin-film magnets 71 and 72. As a result, a uniform magnetic field can be applied to the entire magnetic thin film 60.

In addition, since the thin-film magnets 71 and 72 are provided in the interior space 40, the distance between the magnetic thin film 60 and the thin-film magnets 71 and 72 can be reduced, and simpler design and more cost-effective manufacturing can be achieved.

The structures of resin sealing devices and resin sealing methods according to other modifications and embodiments of the present disclosure will be described. It should be noted that, in modifications and embodiments described below, descriptions of the same matters as the first embodiment are omitted, and only the different points will be described. In particular, the same operations and effects resulting from the same structure will not be described sequentially.

### Second Embodiment

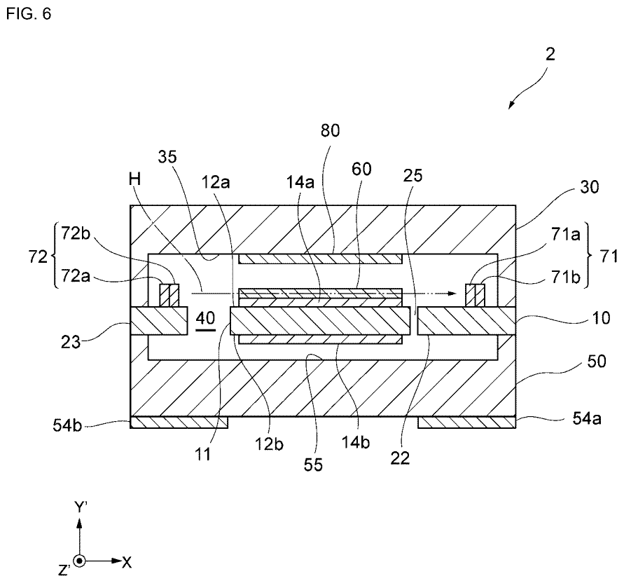

Next, the structure of a resonant magnetic sensor 2 according to a second embodiment will be described with reference to FIG. 6. FIG. 6 is a cross-sectional view schematically illustrating the structure of a resonant magnetic sensor according to the second embodiment.

Unlike the first embodiment, in the second embodiment, the upper lid 30 is made of a material with high laser transmissivity, and a getter layer 80 is provided at a position that does not overlap the thin-film magnets 71 and 72 in plan view on a side of the upper lid 30 that faces the vibrating portion 21. The getter layer 80 suctions foreign substances generated when the thin-film magnets 71 and 72 are trimmed. As a result, after the vibrating portion 21 is sealed by the upper lid 30 and the lower lid 50, the thin-film magnets 71 and 72 can be trimmed with a laser through the upper lid 30 to adjust the magnetic field characteristics. In addition, since the getter layer 80 suctions the foreign substances generated during trimming of the thin-film magnets 71 and 72, performance degradation caused by the foreign substances can be suppressed.

Laser entry through the upper lid 30 is assumed in the present embodiment, but the present disclosure is not limited to this example. For example, when the thin-film magnets 71 and 72 are provided on a side of the quartz crystal vibrating element 10 that faces the lower lid 50, incident laser light through the lower lid 50 can be used to perform trimming by the lower lid 50 being made of a material with high laser permeability. At this time, a getter layer may be provided on a side of the lower lid 50 that faces the vibrating portion 21.

### Third Embodiment

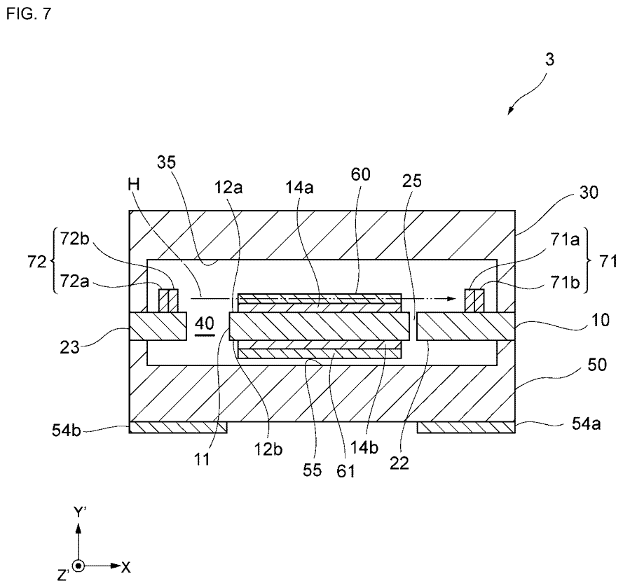

Next, the structure of a resonant magnetic sensor 3 according to a third embodiment will be described with reference to FIG. 7. FIG. 7 is a cross-sectional view schematically illustrating the structure of the resonant magnetic sensor 3 according to the third embodiment.

Unlike the first embodiment, in the third embodiment, a magnetic thin film 61 is further provided on the lower surface of the second excitation electrode 14b of the vibrating portion 21. In addition, the magnetic thin film 61 has magnetostriction characteristics that are exactly opposite to those of the magnetic thin film 60. As a result, the magnetostriction effect in a two-layer structure including magnetic thin films 60 and 61 can be obtained, and a magnetic sensor with higher sensitivity can be provided.

The thin-film magnets 71 and 72 are provided on a side of the quartz crystal vibrating element 10 that faces the upper lid 30 in the present embodiment, but the present disclosure is not limited to this example. For example, by additionally providing a thin-film magnet on a side of the quartz crystal vibrating element 10 that faces the lower lid 50, a uniform magnetic field can also be applied to the magnetic thin film 61 like the magnetic thin film 60, and accordingly, more accurate detection is enabled.

### Fourth Embodiment

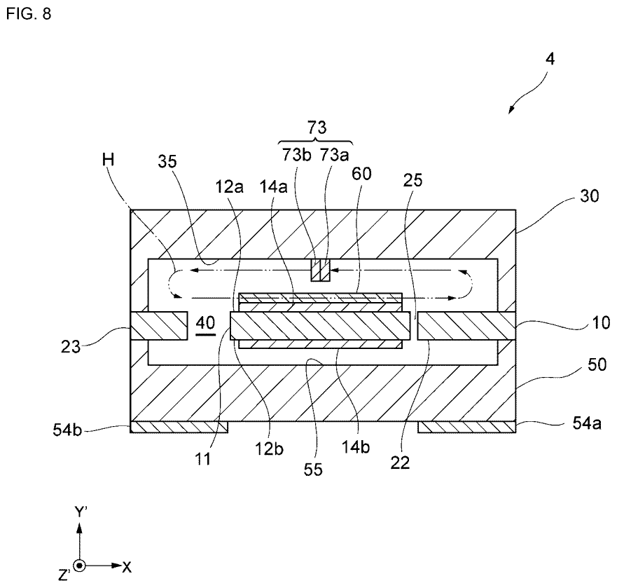

Next, the structure of a resonant magnetic sensor 4 according to a fourth embodiment will be described with reference to FIG. 8. FIG. 8 is a cross-sectional view schematically illustrating the structure of the resonant magnetic sensor 4 according to the fourth embodiment.

The arrangement of the thin-film magnets in the fourth embodiment is different from that in the first embodiment. Specifically, the thin-film magnets 71 and 72 are provided on the holding portion 23 with the magnetic thin film 60 therebetween in the first embodiment, but the thin-film magnet 73 is provided on a side of the upper lid 30 that faces the vibrating portion 21 in the present embodiment. Also in this case, since the magnetic field H passes through the magnetic thin film 60 in the positive X-axis direction as illustrated in FIG. 8, a bias magnetic field can be applied. It should be noted that the thin-film magnet 73 is provided on the upper lid 30 in the present embodiment, but the present disclosure is not limited to this example. For example, the thin-film magnet may be provided on a side of the lower lid 50 that faces the vibrating portion 21.

Some or all of the embodiments of the present disclosure will be additionally described. It should be noted that the present disclosure is not limited to the additional description below.

<1> As described above, according to an aspect of the present disclosure, there is provided a resonant magnetic sensor that detects a magnetic field, the resonant magnetic sensor comprising: a vibrating element that includes a vibrating portion having a first main surface and a second main surface that faces away from the first main surface, an upper electrode on the first main surface of the vibrating portion, and a lower electrode on the second main surface of the vibrating portion; an upper lid on a side of the vibrating element closer to the upper electrode; a lower lid on a side of the vibrating element closer to the lower electrode; a magnetic thin film on the vibrating portion of the vibrating element; and a thin-film magnet spaced away from the vibrating portion in an interior space enclosed by the upper lid and the lower lid such that a magnetic field is applied to the magnetic thin film.

In the aspect described above, a high-sensitive magnetic sensor can be provided by a bias magnetic field being applied to the magnetic thin film. In addition, by the thin-film magnet being provided away from the vibrating portion, the magnetic field can be applied to the magnetic thin film without the vibration characteristics of the vibrating element being hindered. Furthermore, by the magnetic thin film and the thin-film magnet being provided in a vibration space sealed by the upper lid and the lower lid, the distance between the magnetic thin film and the thin-film magnet can be reduced as compared with the structure in which the thin-film magnet is provided externally, and accordingly, simpler and more cost-effective design can be achieved.

<2> According to an aspect, the resonant magnetic sensor according to <1>, wherein the magnetic thin film and the thin-film magnet are on a single plane.

In the aspect described above, a uniform magnetic field can be applied to the entire magnetic thin film.

<3> According to an aspect, the resonant magnetic sensor according to <1> or <2>, wherein the vibrating element includes a holding portion around at least a portion of the vibrating portion in a plan view thereof and a holding arm that connects the holding portion and the vibrating portion to each other, the upper lid and the lower lid are connected to the holding portion, and the thin-film magnet is on the holding portion or the holding arm.

<4> According to an aspect, the resonant magnetic sensor according to <3>, wherein the holding arm is between the vibrating portion and the thin-film magnet, and a through-hole or a recessed portion that passes through the vibrating portion in a thickness direction of the vibrating portion is in a region between the magnetic film and the holding arm of the vibrating portion.

In the aspect described above, the confinement capability of vibration generated by the vibrating portion can be improved by the through-hole or the recessed portion.

<5> According to an aspect, the resonant magnetic sensor according to <4>, wherein the through-hole or the recessed portion is in a slit shape extending in a direction intersecting a direction in which the magnetic thin film and the holding arm are arranged in the plan view.

In the aspect described above, the confinement capability of vibration can be further improved.

<6> According to an aspect, the resonant magnetic sensor according to any one of <3> to <5>, wherein the holding portion surrounds the vibrating portion in the plan view, and the thin-film magnet includes a first thin-film magnet in a first region of the holding portion and a second thin-film magnet in a second region of the holding portion, the second region being opposite to the first region with the magnetic thin film therebetween.

In the aspect described above, since the first thin-film magnet and the second thin-film magnet face each other, a uniform magnetic field can be applied to the vibrating portion between the first thin-film magnet and the second thin-film magnet and the entire magnetic thin film.

<7> According to an aspect, the resonant magnetic sensor according to any one of <1> to <6>, wherein the thin-film magnet is on at least one of the upper lid and the lower lid.

<8> According to an aspect, the resonant magnetic sensor according to any one of <1> to <7>, wherein the magnetic thin film is on at least one of a surface of the upper electrode that faces the upper lid in the vibrating portion and a surface of the lower electrode that faces the lower lid in the vibrating portion.

In the aspect described above, by two layers of magnetic thin films being provided on the upper electrode side and the lower electrode side, the magnetic sensor with higher sensitivity can be provided.

<9> According to an aspect, the resonant magnetic sensor according to any one of <1> to <8>, wherein at least one of the upper lid and the lower lid is made of a material through which laser light for trimming the thin-film magnet is transmittable.

In the aspect described above, by the thin-film magnet being trimmed after the vibrating element is sealed by the upper lid and lower lid, the magnetic field characteristics to be applied by the thin-film magnet can be adjusted.

<10> According to an aspect, the resonant magnetic sensor according to any one of <1> to <9>, further comprising a getter layer that suctions a foreign substance generated from trimming the thin-film magnet is in a region of at least one of the upper lid and the lower lid that faces the vibrating portion, and the getter layer is at a position that does not overlap the thin-film magnet in the plan view.

In the aspect described above, since the getter layer suctions the foreign substance generated during trimming of the thin-film magnet, degradation of vibration characteristics due to adhesion of the foreign substance to the vibrating portion can be prevented.

It should be noted that the embodiments described above are adopted to facilitate the understanding of the present disclosure and are not intended to limit the interpretation of the present disclosure. The present disclosure may be modified or improved without being departed from the spirit, and equivalents thereof are also included in the present disclosure. That is, any modifications made as appropriate by those skilled in the art to the embodiments are included within the scope of the present disclosure as long as the modifications have the features of the present disclosure. For example, the components of the embodiments and the arrangement, the materials, the conditions, the shapes, the sizes, and the like thereof are not limited to those illustrated and can be changed as appropriate. In addition, the components of the embodiments can be combined as technically possible, and any combination of these components is included within the scope of the present disclosure as long as the combination has the features of the present disclosure.

### REFERENCE SIGNS LIST

1, 2, 3, 4 resonant magnetic sensor
10 quartz crystal vibrating element
11 quartz crystal blank
12a first main surface
12b second main surface
14a first excitation electrode
14b second excitation electrode
21 vibrating portion
22 holding arm
23 holding portion
25 through-hole
30 upper lid (first lid)
31 upper surface portion
32 side surface portion
35 recessed portion
40 interior space
50 lower lid (second lid)
51 lower surface portion
52 side surface portion
54a, 54b outer electrode
55 recessed portion
60, 61 magnetic thin film
71, 72, 73 thin-film magnet
71a, 72a, 73a south pole
71b, 72b, 73b north pole
80 getter layer
H magnetic field
L1 length of magnetic thin film in Z′-axis direction
L2 length of thin-film magnet in Z′-axis direction
L3 length of through-hole in Z′-axis direction

1. A resonant magnetic sensor that detects a magnetic field, the resonant magnetic sensor comprising:
a vibrating element that includes a vibrating portion having a first main surface and a second main surface that faces away from the first main surface, a first electrode on the first main surface of the vibrating portion, and a second electrode on the second main surface of the vibrating portion;
a first lid on a side of the vibrating element closer to the first electrode;
a second lid on a side of the vibrating element closer to the second electrode;
a magnetic film on the vibrating portion of the vibrating element; and
a film magnet spaced away from the vibrating portion in an interior space enclosed by the first lid and the second lid such that a magnetic field is applied to the magnetic film.

2. The resonant magnetic sensor according to claim 1, wherein the magnetic film and the film magnet are on a single plane.

3. The resonant magnetic sensor according to claim 1,
wherein the vibrating element includes a holding portion around at least a portion of the vibrating portion in a plan view thereof and a holding arm that connects the holding portion and the vibrating portion to each other,
the first lid and the second lid are connected to the holding portion, and
the film magnet is on the holding portion or the holding arm.

4. The resonant magnetic sensor according to claim 3,
wherein the holding arm is between the vibrating portion and the film magnet, and
a through-hole or a recessed portion that passes through the vibrating portion in a thickness direction of the vibrating portion is in a region between the magnetic film and the holding arm of the vibrating portion.

5. The resonant magnetic sensor according to claim 4, wherein the through-hole or the recessed portion is in a slit shape extending in a direction intersecting a direction in which the magnetic film and the holding arm are arranged in the plan view.

6. The resonant magnetic sensor according to claim 5, wherein a length L1 of the magnetic film in a first direction, a length L2 of the film magnet in the first direction, and a length L3 of the through-hole in the first direction are equal to each other.

7. The resonant magnetic sensor according to claim 5, wherein at least two of a length L1 of the magnetic film in a first direction, a length L2 of the film magnet in the first direction, and a length L3 of the through-hole in the first direction are different from each other.

8. The resonant magnetic sensor according to claim 3,
wherein the holding portion surrounds the vibrating portion in the plan view, and
the film magnet includes a first film magnet in a first region of the holding portion and a second film magnet in a second region of the holding portion, the second region being opposite to the first region with the magnetic film therebetween.

9. The resonant magnetic sensor according to claim 1, wherein the film magnet includes a first film magnet in a first region of the interior space and a second film magnet in a second region of the interior space, the second region being opposite to the first region with the magnetic film therebetween.

10. The resonant magnetic sensor according to claim 9, wherein the first film magnet and the second film magnet are in a same plane as at least a portion of the magnetic film.

11. The resonant magnetic sensor according to claim 9, wherein a south pole of the first film magnet faces the magnetic film, and a north pole of the second film magnet faces the magnetic film.

12. The resonant magnetic sensor according to claim 1, wherein the film magnet is on at least one of the first lid and the second lid.

13. The resonant magnetic sensor according to claim 1, wherein the magnetic film is on at least one of a surface of the first electrode that faces the first lid in the vibrating portion and a surface of the second electrode that faces the second lid in the vibrating portion.

14. The resonant magnetic sensor according to claim 1, wherein the magnetic film includes a first magnetic film on a surface of the first electrode that faces the first lid, and a second magnetic film on a surface of the second electrode that faces the second lid.

15. The resonant magnetic sensor according to claim 14, wherein the film magnet includes a first film magnet in a first region of the interior space and a second film magnet in a second region of the interior space, the second region being opposite to the first region with one of the first magnetic film and the second magnetic film therebetween.

16. The resonant magnetic sensor according to claim 15, wherein the first film magnet and the second film magnet are in a same plane as at least a portion of the one of the first magnetic film and the second magnetic film.

17. The resonant magnetic sensor according to claim 15, wherein a south pole of the first film magnet faces the one of the first magnetic film and the second magnetic film, and a north pole of the second film magnet faces the one of the first magnetic film and the second magnetic film.

18. The resonant magnetic sensor according to claim 1, wherein at least one of the first lid and the second lid is made of a material through which laser light for trimming the film magnet is transmittable.

19. The resonant magnetic sensor according to claim 18, further comprising:
a getter layer that suctions a foreign substance generated from trimming the film magnet is in a region of at least one of the first lid and the second lid that faces the vibrating portion, and
the getter layer is at a position that does not overlap the film magnet in a plan view.
